(19) United States
(12) Patent Application Publication
(10) Pub. No.: US 2015/0028358 A1
(43) Pub. Date: Jan. 29, 2015

(54) PACKAGE STRUCTURE OF AN OPTICAL MODULE

(71) Applicant: LINGSEN PRECISION INDUSTRIES, LTD, Taichung City (TW)

(72) Inventors: Ming-Te TU, Taichung City (TW); Yu-Shiang CHEN, Taichung City (TW)

(73) Assignee: LINGSEN PRECISION INDUSTRIES, LTD, Taichung City (TW)

(21) Appl. No.: 14/072,187

(22) Filed: Nov. 5, 2013

(30) Foreign Application Priority Data
Jul. 25, 2013 (TW) 102126691

(51) Int. Cl. H01L 33/52; H01L 31/173

(52) U.S. Cl. CPC H01L 33/52; H01L 31/173
USPC 257/82; 438/25

(57) ABSTRACT

The present invention relates to a package structure of an optical module. The light emitting chip and the light receiving chip are disposed on the light emitting region and the light receiving region of the substrate, respectively. Two encapsulating gels are coated on the light emitting chip and the light receiving chip to form a first and a second hemispherical lens portions thereon, respectively. A cover is affixed on the substrate and each of the encapsulating gels and has a light emitting hole and a light receiving hole, where the first and second lens portions are accommodated, respectively. In this way, the package structure of an optical module of the present invention can be made with the encapsulating gels of different curvatures according to different needs to improve the luminous efficiency of the light emitting chip effectively and to improve the reception efficiency of the light receiving chip.

### BACKGROUND OF THE INVENTION

1. Field of the Invention

The present invention relates to a package structure, especially related to a package structure of an optical module.

2. Descriptions of the Related Art

Currently, optical proximity sensing modules have become a mainstream technology choice of the new generation of intelligent electronic devices (such as smart phones). When the electronic device is close to someone's ears (face detection) or placed in a pocket, the module will immediately turn off the screen display to save power and prevent accidental screen presses to provide a better user experience. The action principle of the module is emitting a light source with a light emitting chip, such as a light emitting diode (LED), the light is reflected by the surface of an object and is then projected onto a light receiving chip to be converted to electrical signals for subsequent processing.

However, after the proximity of the conventional optical sensing module in the package is complete, the power of the light emitted by the light emitting chip of the module often has been greatly reduced after the light is reflected by the surface. The light signals received by the adjacent light receiving chip is poor or even not received, which causes the signal of the recited intelligent electronic devices can not be stable and accurate for interpretation.

### BRIEF SUMMARY OF THE INVENTION

The main objective of the present invention is to provide a package structure of an optical module to effectively improve the luminous efficiency of the light emitting chip and to improve the defect of the reception of the light receiving chip.

The secondary objective of the present invention is to provide a package structure of an optical module to effectively decrease packaging cost and enhance the competitiveness of products.

In order to achieve the above objectives, the package structure of an optical module of the present invention comprises a substrate, a light emitting chip, a light receiving chip, two encapsulating gels and a cover. The substrate is defined with a light receiving region and a light emitting region. The light receiving chip and the light emitting chip are disposed on the light receiving region and the light emitting region of the substrate, respectively. Each of the two encapsulating gels is coated on the light receiving chip and the light emitting chip, respectively, to form a first lens portion and a second lens portion, which are hemispheres. The cover is affixed on the substrate and each of the encapsulating gels, respectively, by a capping process. The cover has a light emitting hole and a light receiving hole, and the light emitting hole and the light receiving hole are located above the light emitting chip and the light receiving chip, respectively. The first lens portion and the second lens portion are accommodated in the light emitting hole and the light receiving hole, respectively.

A curvature of each of the first lens portion and the second lens portion of each of the encapsulating gels are the same or different.

Each of the encapsulating gels is made of resin.

The cover is integrated and made of opaque resin.

The substrate is a non-ceramic substrate, which comprises an organic Bismaleimide Triazine substrate.

The present invention further provides a packaging method of an optical module, and the method comprises the following steps of

(a) defining a light emitting region and a light receiving region on a substrate;

(b) electrically connecting a light receiving chip and a light emitting chip on the substrate;

(c) forming light transmissive encapsulating gels on the light receiving chip and the light emitting chip; and

(d) covering an opaque cover on the encapsulating gels and the substrate.

The electrically connecting is by a wire bonding process and a die attaching process.

The encapsulating gels are formed by a molding process.

The cover is formed by a capping process.

The packaging method further comprises a step (e) of cutting or punching the optical module made in the step (a) to step (d).

In this way, the package structure of an optical module of the present invention can be made with the encapsulating gels of different curvatures according to different needs to improve the luminous efficiency of the light emitting chip effectively and to improve the reception quality of the light receiving chip. Moreover, the cover is covered on the substrate with a capping process, which simplified the package structure of the optical module and reduces the packaging cost.

To provide a further understanding of the composition, characteristics and purpose of the present invention, the following are descriptions describe several embodiments of the present invention to explain the drawings in detail for people skilled in this technical field can implement. The following description lists the embodiments to illustrate the technical contents and characteristics of the present invention. People have a general knowledge of this technical field of the present invention can proceed with various simple modifications, replacements, or member omitting belonging to the scope of the present invention intended to protect.

### BRIEF DESCRIPTION OF THE SEVERAL VIEWS OF THE DRAWINGS

The following illustrates embodiments and corresponding diagrams to describe the technical content and characteristics of the present invention.

FIG. 1 is a top view of a preferred embodiment of the present invention;

FIG. 2 is a cross-sectional view along the 2-2. section line of FIG. 1 of a preferred embodiment of the present invention; and

FIG. 3 is a packaging flow diagram of a preferred embodiment of the present invention.

### DETAILED DESCRIPTION OF THE INVENTION

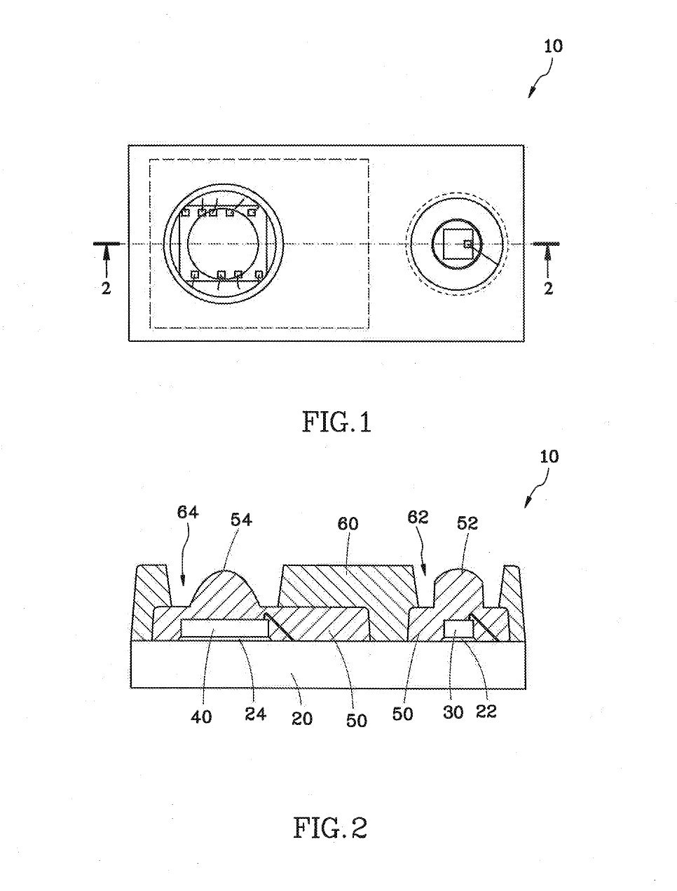

Please refer to FIG. 1 and FIG. 2. The package structure of an optical module 10 provided by a preferred embodiment of the present invention is cut from a module of the package array and comprises a substrate 20, a light receiving chip 30, a light emitting Chip 40, two encapsulating gels 50 and a cover 60.

The substrate 20 in the preferred embodiment is a non-ceramic substrate, such as a Bismaleimide Triazine (known as BT) substrate or a glass fiber (known as FR4) substrate made of organic materials. Thereby, the material cost of the substrate 20 is low. The surface of the substrate 20 is defined with a light receiving region 22 and a light emitting region 24.

The light emitting chip 30 and the light receiving chip 40 are treated by a die attaching process and a wire bonding process and are disposed on the light receiving region 22 and the light emitting region 24 of the substrate 20. The light emitting chip 30 is used to emit light, and the light receiving chip 40 is used to receive the light emitted from the light emitting chip 30.

Each of the encapsulating gels 50 is made of light transmissive resin, such as transparent epoxy resin. Each of the encapsulating gels 50 is coated on the light receiving chip 30 and the light emitting chip 40, respectively, and each of the encapsulating gels 50 is disposed on the light emitting chip 30 and the light receiving chip 40, respectively, to form a first lens portion 52 and a second lens portion 54, which are hemispheres.

The cover 60 is integrally molded with the opaque resin, such as opaque epoxy resin. The cover 60 is disposed on the substrate 20 and each of the encapsulating gels 50 by a capping process. The cover 60 has a light emitting hole 62, a light receiving hole 64. The light emitting hole 62 and the light receiving hole 64 are located above the light emitting chip 30 and the light receiving chip 40, respectively, and the light emitting chip 30 and the light receiving chip 40 are accommodated in the light emitting hole 62 and the light receiving hole 64, respectively In the preferred embodiment of the present invention, the curvatures of the first and second lens portions 52, 54 can be the same or different to meet the different using needs. When the curvature of the first lens portion 52 is larger, the light emitting region of the light emitting chip 30 covers larger. When the curvature of the second lens portion 54 is smaller, the second lens 54 focuses the reflected light more effectively. Therefore, the optical module of the present invention can effectively improve the luminous efficiency of the light emitting chip 30 and improve the poor reception of the light receiving chip 40.

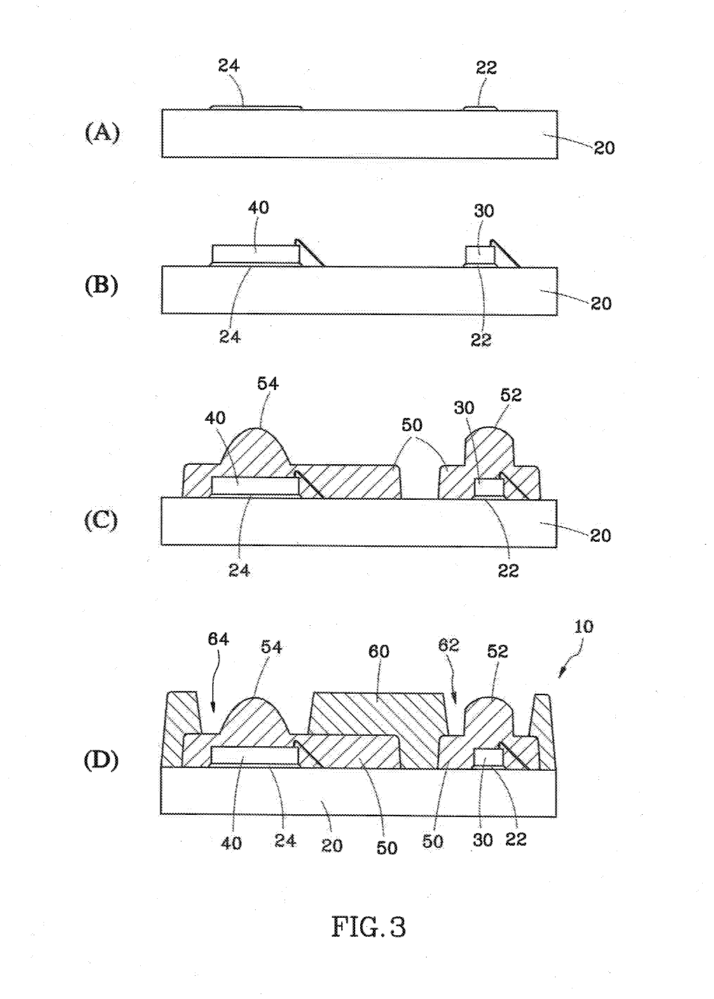

Referring again to FIGS. 3(A) to 3(D), which show the packaging process of the optical module of the present invention. The first step A is defining the light emitting region 22 and the light receiving region 24 on a single substrate 20 of each substrate array. The second step B is disposing the light emitting chip 30 and the light receiving chip 40 on the light emitting region 22 and the light receiving region 24 of the substrate 20, respectively, by a die attaching process and a wire bonding process. The third step C is molding each of the light transmissive encapsulating gels 50 on the light emitting chip 30 and the light receiving chip 40 to form the first lens portion 52 and the second lens portion 54, which are hemispheres. The fourth step D is covering the opaque cover 60 on the substrate 20 and the encapsulating gels 50 by a capping process of the packaging method. The cover 60 has a light emitting hole 62 and the light receiving hole 64, and the light emitting hole 62 and the light receiving hole 64 are located above the light emitting chip 30 and the light receiving chip 40, respectively. The first lens portion 52 and the second lens portion 54 of each of the encapsulating gels 50 is respectively disposed in the light emitting hole 62 and the light receiving hole 64. Thereby, a package structure of the optical module the present invention is completed.

According to the preferred embodiment of the present invention, the second step B to the fourth step D is to position the hemispherical mold of the first lens portion 52 and the second lens portion 54 to a predetermined position aligning the light emitting chip 30 and the light receiving chip 40 on the surface of the substrate 20. Then, the light transmissive resin is filled in the mold to cover each of the chips 30, 40. The light transmissive resin forms the encapsulating gels 50, which are hemispheres after being shaped and retreated from the mold. Finally, the cover 60, which is previously processed, is adhered to cap on the substrate 20 and/or each of the encapsulating gels 50 to complete the package structure 10 of the optical module of the present invention. Thereby, the packaging method simplifies the conventional complicated packaging process, decreases the overall packaging cost and gets a better competitiveness in the industry.

In summary, the light emitted from the light emitting chip 30 of the optical module of the present invention passes through the first lens portion 52 of the encapsulating gels 50 and then passes through the light emitting hole 62 of the cover 60 to be projected to the surface of the object. The light reflected from the surface of the object is received by the light receiving hole 64 of the cover 60 and is projected to the second lens portion 54 of the encapsulating gels 50. The light is focused and emitted to the light receiving chip 40, and the light receiving chip 40 converts the received light signals into electrical signals for operation processing. When emitting and receiving the light, the first lens portion 52 of the encapsulating gels 50 improves the luminous power of the light emitting chip 30, and the second lens portion 4 of the encapsulating gels 50 enhances the reception power of the light receiving chip 40. Thereby, the light projected on the uneven surface of the object by the light emitting chip 30 can be reliably and stably received by the light receiving chip 40 after being reflected. The cover 60 is covered on the substrate 20 with a capping process, which simplified the package structure 10 of the optical module and reduces the packaging cost.

The constituent elements in the above embodiments of the present invention are only for illustration and are not intended to limit the scope of the present invention. Other substitutions, equivalent elements or changes should be covered by the scope of the claim of the present invention.

What is claimed is:

1. A packaging method of an optical module, the method comprising the following steps of:
(a) defining a light emitting region and a light receiving region on a substrate;
(b) electrically connecting a light receiving chip and a light emitting chip on the substrate;
(c) forming light transmissive encapsulating gels on the light receiving chip and the light emitting chip; and
(d) covering an opaque cover on the encapsulating gels and the substrate.

2. The packaging method of the optical module as claimed in claim 1, wherein the electrically connecting is by a wire bonding process and a die attaching process.

3. The packaging method of the optical module as claimed in claim 1, wherein the encapsulating gels are formed by a molding process.

4. The packaging method of the optical module as claimed in claim 1, wherein the cover is formed by a capping process.

5. The packaging method of the optical module as claimed in claim 1, further comprising a step (e) of cutting or punching the optical module made in the step (a) to step (d).

6. A package structure of an optical module, comprising:
a substrate being defined with a light receiving region and a light emitting region;
a light receiving chip disposed on the light receiving region of the substrate;
a light emitting chip disposed on the light emitting region of the substrate;
two encapsulating gels made of a light transmissive material and coated on the light receiving chip and the light emitting chip, respectively, to form a first lens portion and a second lens portion, which are hemispheres; and
a cover disposed on the substrate and having a light emitting hole and a light receiving hole, and the light emitting hole and the light receiving hole being located above the light emitting chip and the light receiving chip, respectively, and the first lens portion and the second lens portion being accommodated in the light emitting hold and the light receiving hole, respectively.

7. The package structure of the optical module as claimed in claim 6, wherein a curvature of each of the first lens portion and the second lens portion of each of the encapsulating gels are the same or different.

8. The package structure of the optical module as claimed in claim 6, wherein each of the encapsulating gels is made of resin.

9. The package structure of the optical module as claimed in claim 6, wherein the cover is integrated and made of opaque resin.

10. The package structure of the optical module as claimed in claim 6, wherein the substrate is a non-ceramic substrate, which comprises an organic Bismaleimide Triazine substrate.
